(19) United States
(12) Patent Application Publication
(10) Pub. No.: US 2026/0150615 A1
(43) Pub. Date: May 28, 2026

(54) Method, System and Computing Device for Temperature Control in Semiconductor Manufacturing Process

(71) Applicant: Premtek International Inc., Hsinchu City (TW)

(72) Inventors: Wu-Lang LIN, Hsinchu City (TW); Bo-Ting LIAO, Hsinchu City (TW); Jeng-Bin CHIU, Hsinchu City (TW); Shao-Ning FAN, Hsinchu City (TW); Jian-Wei HUANG, Hsinchu City (TW); Yi-Liang LIOU, Hsinchu City (TW); Ting-Ju LIN, Hsinchu City (TW)

(73) Assignee: Premtek International Inc., Hsinchu City (TW)

(21) Appl. No.: 19/266,861

(22) Filed: Jul. 11, 2025

(30) Foreign Application Priority Data
Nov. 27, 2024 (TW) 113145843

(51) Int. Cl. H01L 21/67

(52) U.S. Cl. CPC H10P 72/0602

(57) ABSTRACT

A method of temperature control includes, at each of plural process time points of a semiconductor manufacturing process, steps of: in response to obtaining a process temperature value of the temperature of a target semiconductor element that is currently measured by an optical thermometer at the process time point, converting the process temperature value to a converted temperature value by using a conversion model; calculating a temperature difference between the converted temperature value and a preset temperature value corresponding to the process time point; calculating an adjustment parameter based on the temperature difference thus calculated; and controlling a temperature control device based on the adjustment parameter to achieve temperature control.

### CROSS-REFERENCE TO RELATED APPLICATION

This application claims priority to Taiwanese Invention Patent Application No. 113145843, filed on Nov. 27, 2024, the entire disclosure of which is incorporated by reference herein.

### FIELD

The disclosure relates to a method, a system and a computing device for temperature control in a semiconductor manufacturing process.

### BACKGROUND

In a rapid thermal processing (RTP), halogen lamps are usually utilized for heating a semiconductor element (e.g., a wafer) in a process chamber and optical thermometers are usually utilized for measuring temperature of the semiconductor element. However, measurements made by the optical thermometers are prone to be interfered by light emitted from the halogen lamps, and by stray light caused by thermal radiation of other components in the process chamber. Interference with measurements made by the optical thermometers would become relatively more severe in a scenario where a bare wafer is heated by using a scheme of double-sided heating. It is worthy of note that when the semiconductor element being heated is made of relatively-transparent material (e.g., a silicon carbide, SiC, wafer or a sapphire wafer), a signal-to-noise ratio in regard to output of measurement by an optical thermometer and interference caused by stray light would be small, and thereby removing the interference caused by stray light from the output of measurement by the optical thermometer would be difficult. In addition, factors such as coating at a backside of a wafer or uneven roughness of a wafer would adversely impact accuracy of measurement made by an optical thermometer.

Conventionally, covering a semiconductor element with a light-blocking cover is often adopted to reduce interference caused by stray light, but such approach only allows a scheme of single-sided heating to be performed on the semiconductor element, and thus a way of manufacturing the semiconductor element is limited.

Another conventional approach of reducing interference caused by stray light is to utilize signal processing techniques (e.g., the ripple technology) to remove interference caused by stray light from output of measurement by an optical thermometer. However, due to complexity of computations involved therein, such approach requires high-performance hardware, such as high-sampling-rate optical thermometers and high-speed computers that are specifically designed for signal processing, thereby increasing hardware costs.

U.S. Invention Patent Publication Number US5660472 discloses a method for reducing effect of changes in wafer emissivity on temperature measurements by placing a thermal reflector near a back surface of a target substrate to form a reflecting cavity which causes thermal radiation from the substrate to be reflected back to the substrate (and thereby acts like a black body, ideally), and then by inserting a light pipe through the reflector into the cavity to sample radiation from the reflecting cavity and to deliver the sampled light to a pyrometer.. However, such approach is costly due to high prices of materials that have to fit in both optical properties and thermal conductivities. Moreover, a single-sided heating scheme is usually the only choice suitable to be adopted in such approach, i.e., a symmetric heating scheme or a complicated heating scheme may not be adopted, thereby limiting implementation of a heating scheme. Furthermore, thermal stresses caused by uneven heating under the single-sided heating scheme may adversely impact silicon wafer flatness and a process yield.

### SUMMARY

Therefore, an object of the disclosure is to provide a method, a system and a computing device for temperature control in a semiconductor manufacturing process that can alleviate at least one of the drawbacks of the prior art.

According to a first aspect of the disclosure, the semiconductor manufacturing process involves an optical thermometer and a temperature control device. The optical thermometer continuously measures temperature of a target semiconductor element heated by the temperature control device during the semiconductor manufacturing process. The semiconductor manufacturing process has plural successive process time points which correspond respectively to plural preset temperature values. The method includes, at each of the process time points, steps of:
in response to obtaining a process temperature value of the temperature of the target semiconductor element that is currently measured by the optical thermometer at the process time point, converting the process temperature value of the target semiconductor element to a converted temperature value by using a conversion model;
calculating a temperature difference between the converted temperature value and the preset temperature value corresponding to the process time point;
calculating an adjustment parameter based on the temperature difference thus calculated, the adjustment parameter indicating a power of the temperature control device; and
controlling the temperature control device based on the adjustment parameter to achieve temperature control.

According to a second aspect of the disclosure, the semiconductor manufacturing process involves an optical thermometer and a temperature control device. The computing device is electrically connected to the optical thermometer and the temperature control device. The optical thermometer continuously measures temperature of a target semiconductor element heated by the temperature control device during the semiconductor manufacturing process. The semiconductor manufacturing process has plural successive process time points which correspond respectively to plural preset temperature values. The computing device includes a storage, and a processor electrically connected to the storage. The storage is configured to store a conversion model. The processor is configured to, at each of the process time points, in response to obtaining a process temperature value of the temperature of the target semiconductor element that is currently measured by the optical thermometer at the process time point, convert the process temperature value of the target semiconductor element to a converted temperature value by using the conversion model stored in the storage. The processor is further configured to, at each of the process time points, calculate a temperature difference between the converted temperature value and the preset temperature value corresponding to the process time point, and calculate an adjustment parameter based on the temperature difference thus calculated. The adjustment parameter indicates a power of the temperature control device. The processor is further configured to, at each of the process time points, control the temperature control device based on the adjustment parameter to achieve temperature control.

According to a third aspect of the disclosure, the system includes a temperature control device, an optical thermometer, and a computing device that is described in the abovementioned second aspect of the disclosure. The temperature control device includes a carrier and a set of heating modules. The carrier is configured to hold a target semiconductor element. The set of heating modules is configured to heat the target semiconductor element. The optical thermometer is configured to continuously measure temperature of the carrier as temperature of the target semiconductor element.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a system for temperature control in a semiconductor manufacturing process according to an embodiment of the disclosure.

FIG. 2 is a flow chart illustrating a pre-processing procedure of a method of temperature control according to an embodiment of the disclosure.

FIG. 3 is a schematic diagram illustrating an example of performing a filtering process according to an embodiment of the disclosure.

FIG. 4 is a flow chart illustrating the method of temperature control in a semiconductor manufacturing process according to an embodiment of the disclosure.

FIG. 5 is a schematic diagram illustrating an example of performing temperature control based on reference temperature values measured by a reference thermometer according to an embodiment of the disclosure.

FIG. 6 is a schematic diagram illustrating an example of performing temperature control based on converted temperature values obtained by using a conversion model according to an embodiment of the disclosure.

FIG. 7 is a schematic diagram illustrating an example of temperature values in the pre-processing procedure according to an embodiment of the disclosure.

FIG. 8 is a schematic diagram illustrating an example of measuring temperature of a semiconductor element held by a ring according to an embodiment of the disclosure.

FIG. 9 is a schematic diagram illustrating an example of measuring temperature of a semiconductor element held by a susceptor according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

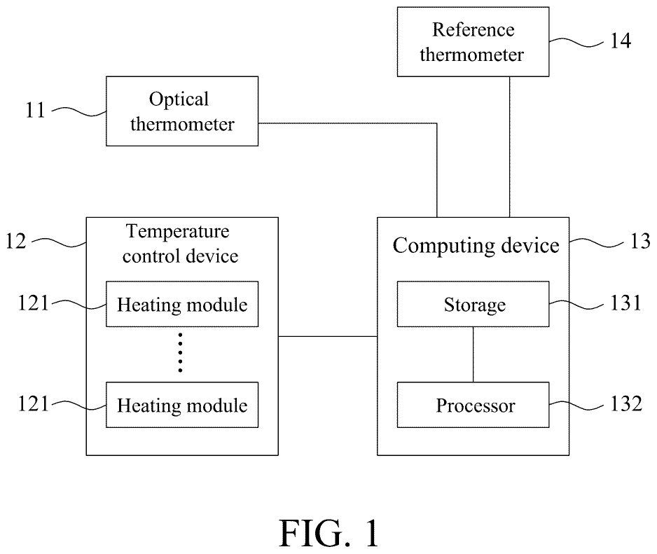

Referring to FIG. 1, an embodiment of a system for temperature control in a semiconductor manufacturing process according to the disclosure is illustrated. The system includes an optical thermometer 11, a temperature control device 12 and a computing device 13. The computing device 13 is electrically connected to the optical thermometer 11 and the temperature control device 12.

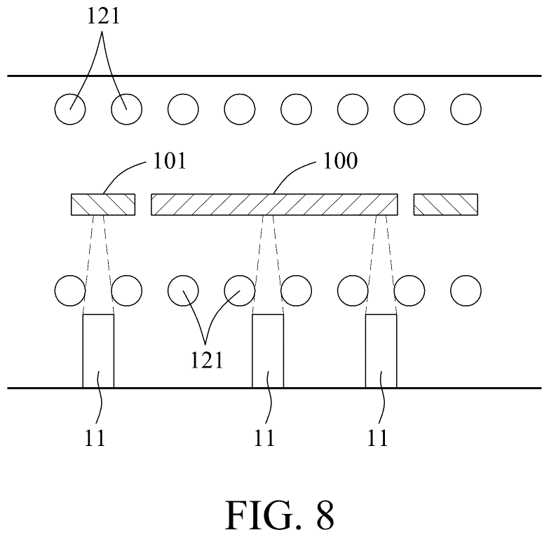

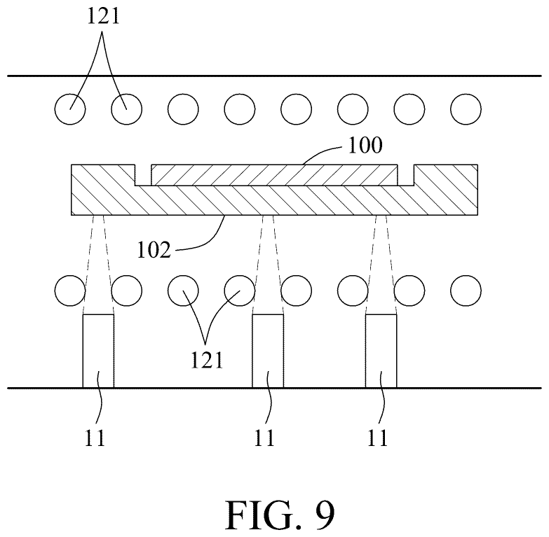

The temperature control device 12 may be implemented by rapid thermal annealing (RTA) equipment, but is not limited thereto. Referring to FIGS. 1, 8 and 9, the temperature control device 12 includes a carrier that is configured to hold a semiconductor element 100 (e.g., a silicon wafer), and a set of heating modules 121 that is configured to heat the semiconductor element 100. In one embodiment, the carrier is a ring 101 as shown in FIG. 8, wherein the ring 101 is represented as a cross section thereof. The ring 101 may be implemented to be an edge ring (which has a structure completely surrounding the semiconductor element 100), a guard ring (which has a structure composed of multiple arc-shaped components), or the like. In one embodiment, the carrier is a susceptor 102 as shown in FIG. 9. The set of heating modules 121 may be implemented by halogen lamps, but is not limited to the disclosure herein and may vary in other embodiments.

The optical thermometer 11 may be implemented by a pyrometer, but is not limited thereto. The optical thermometer 11 is configured to continuously measure temperature of the semiconductor element 100 heated by the temperature control device 12 (specifically, by the set of heating modules 121). Since the carrier and the semiconductor element 100 are close to each other in space, temperature of the carrier is thereby similar to temperature of the semiconductor element 100 when thermal equilibrium occurs. In one embodiment, the optical thermometer 11 is configured to continuously measure the temperature of the carrier as the temperature of the semiconductor element 100.

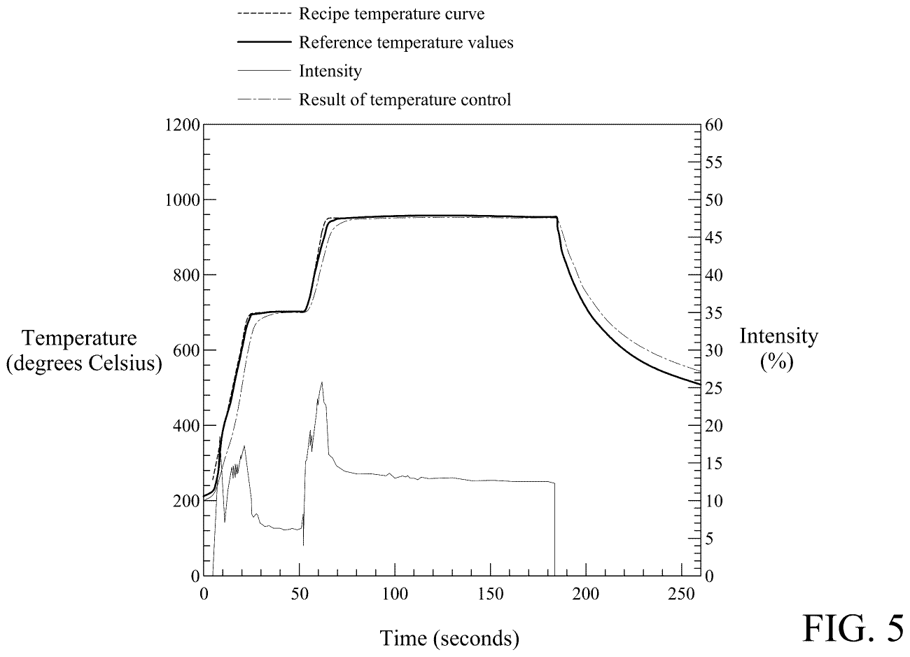

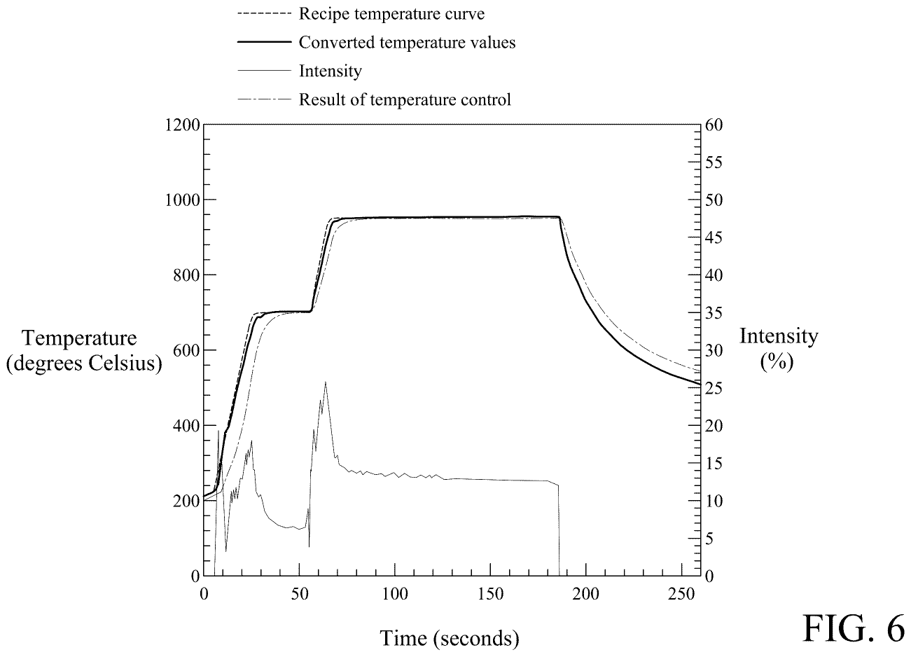

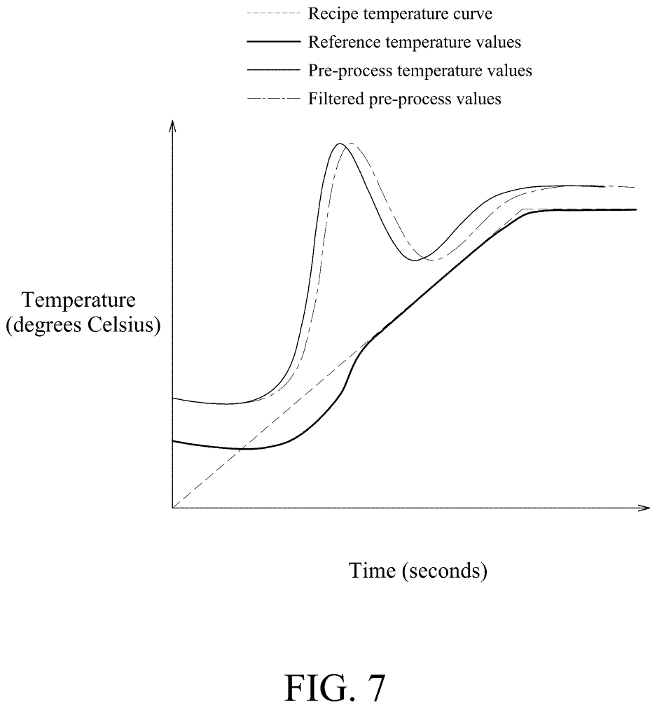

The semiconductor manufacturing process has plural successive process time points which correspond respectively to plural preset temperature values. The process time points are exemplarily a 10^{th} second, a 20^{th} second, a 30^{th} second and so on, from the start of the semiconductor manufacturing process, but are not limited thereto. The preset temperature values are determined in advance according to a technician's experience and expertise, and cooperatively form a recipe temperature curve (for example, a dashed curve plotted in FIG. 5, FIG. 6 or FIG. 7). The temperature control device 12 is configured to heat the semiconductor element 100 according to the recipe temperature curve (i.e., according to the preset temperature values respectively at the process time points).

It should be noted that by virtue of the principle of reproducibility, when a manufacturing process is stable, recipes (e.g., parameters related to settings of manufacturing machines, the recipe temperature curve, and so on) used in the manufacturing process are fixed. The abovementioned recipe temperature curve is one of such recipes, and it is expected that results respectively of multiple times of temperature control performed by the temperature control device 12 for heating the semiconductor element 100 according to the recipe temperature curve would be substantially similar or even identical in view of history of heating. For example, in a first manufacturing process, the temperature control device 12 is utilized to heat a first semiconductor component (e.g., a silicon wafer) according to the recipe temperature curve for ten minutes; similarly, in a second manufacturing process, the temperature control device 12 is again utilized to heat a second semiconductor component that is identical to the first semiconductor component according to the recipe temperature curve for ten minutes. Then, at the same time point (e.g., at a third minute) in each of the first manufacturing process and the second manufacturing process, temperature of the first semiconductor component is similar to or even identical to temperature of the second semiconductor component, and a temperature value of the temperature of the first semiconductor component and a temperature value of the temperature of the second semiconductor component each measured by the optical thermometer 11 are accordingly similar or even identical.

The computing device 13 may be implemented to be a personal computer such as a desktop computer, a laptop computer, a notebook computer or a tablet computer, but implementation thereof is not limited to what are disclosed herein and may vary in other embodiments. The computing device 13 includes a storage 131, and a processor 132 that is electrically connected to the storage 131.

The storage 131 may be implemented by random access memory (RAM), double data rate synchronous dynamic random access memory (DDR SDRAM), read only memory (ROM), programmable ROM (PROM), flash memory, a hard disk drive (HDD), a solid state disk (SSD), electrically-erasable programmable read-only memory (EEPROM) or any other volatile/non-volatile memory devices, but is not limited thereto. The storage 131 is configured to store a conversion model.

The processor 132 may be implemented by a central processing unit (CPU), a microprocessor, a micro control unit (MCU), a system on a chip (SoC), or any circuit configurable/programmable in a software manner and/or hardware manner to implement functionalities discussed in this disclosure.

In one embodiment, the system further includes a reference thermometer 14 (see FIG. 1), and the computing device 13 is further electrically connected to the reference thermometer 14. The reference thermometer 14 may be implemented by a thermocouple, but is not limited thereto. The reference thermometer is configured to continuously measure temperature of the semiconductor element 100 heated by the temperature control device 12. It is worthy of note that compared with the optical thermometer 11 (e.g., the pyrometer), the reference thermometer 14 (e.g., the thermocouple) is capable of more accurately measuring temperature of the semiconductor element 100 because the reference thermometer 14 suffers from less interference caused by stray light than does the optical thermometer 11. However, the reference thermometer 14 is required to make contact with the semiconductor element 100 for measurement, so the semiconductor element 100 could no longer be further utilized after the temperature of the semiconductor element 100 has been measured by the reference thermometer 14.

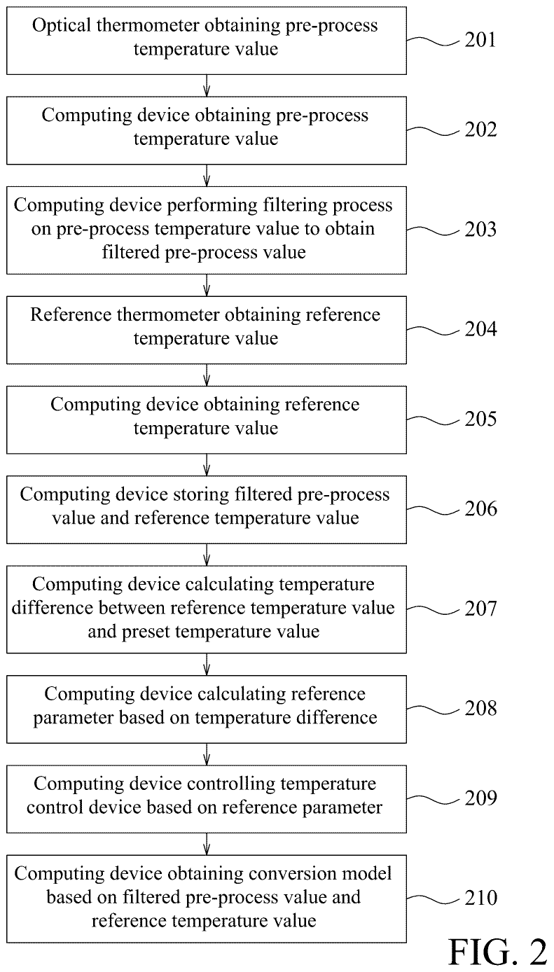

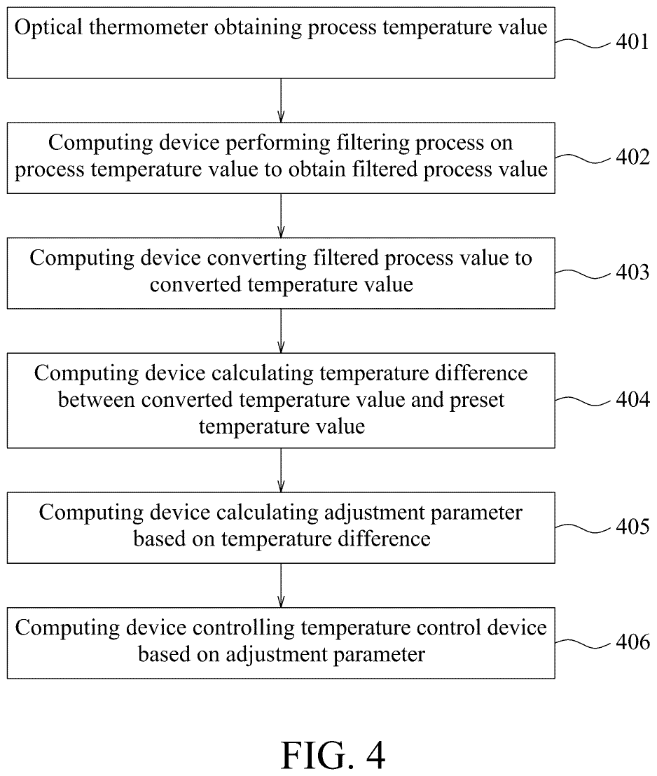

Referring to FIGS. 2 and 4, an embodiment of a method of temperature control according to the disclosure is illustrated. The method is adapted to be implemented by the system that was previously described. The method includes a pre-processing procedure for establishing the conversion model, and a semiconductor manufacturing process for achieving temperature control by using the conversion model thus established.

The pre-processing procedure has plural successive pre-process time points that correspond respectively to the process time points. For example, the pre-process time points are a 10^{th} second, a 20^{th} second, a 30^{th} second and so on, from the start of the pre-processing procedure, but are not limited thereto. The pre-process time points correspond respectively to the preset temperature values. During the pre-processing procedure, the set of heating modules 121 of the temperature control device 12 heats a test semiconductor element (e.g., a silicon wafer) held by the carrier, and the reference thermometer 14 and the optical thermometer 11 continuously measure temperature of the test semiconductor element heated by the temperature control device 12. The pre-processing procedure includes steps 201 to 210 as shown in FIG. 2 and delineated below. It should be noted that steps 201 to 209 are executed at each of the pre-process time points for collecting temperature-related data obtained by the reference thermometer 14 and the optical thermometer 11, and step 210 is executed at the end of the pre-processing procedure for obtaining the conversion model based on the temperature-related data thus collected.

In step 201, the optical thermometer 11 measures the temperature of the test semiconductor element to obtain a pre-process temperature value of the temperature of the test semiconductor element, and outputs the pre-process temperature value to the computing device 13.

In step 202, the processor 132 of the computing device 13 obtains the pre-process temperature value of the test semiconductor element that is currently measured by the optical thermometer 11 at the pre-process time point.

In step 203, the processor 132 performs a filtering process on the test temperature value of the test semiconductor element obtained at the pre-process time point so as to obtain a filtered pre-process value.

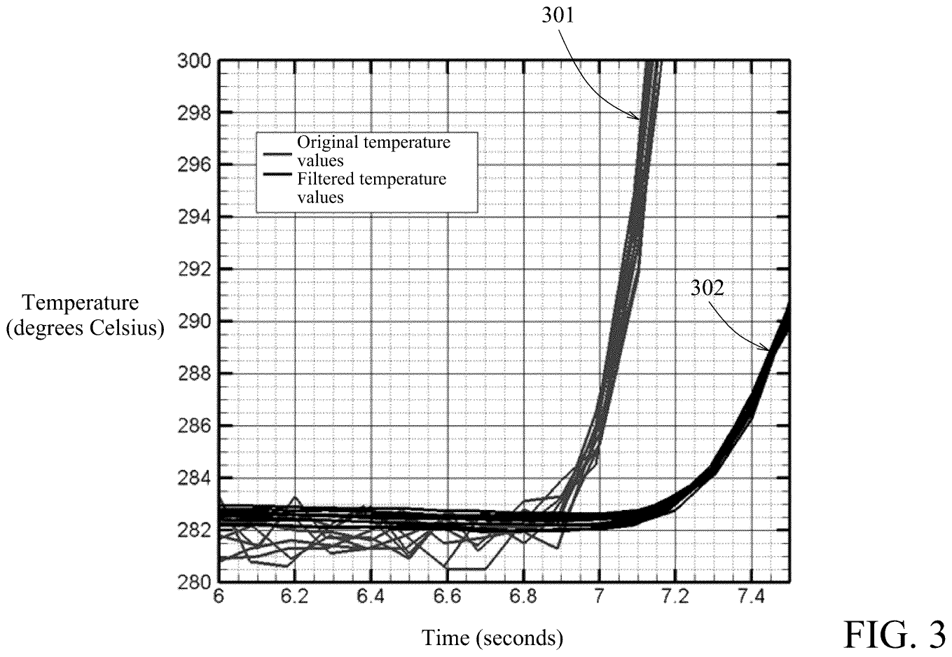

It is worthy of note that there are relatively greater errors in measurement of the optical thermometer 11 when temperature being measured is within a range of relatively low temperatures (from 280 to 285 degrees Celsius in this embodiment, but is not limited thereto), and the filtering process performed in step 203 would help reduce such errors and as well benefit temperature control that is to be performed based on the measurement. Referring to FIG. 3 where the optical thermometer 11 was used to continuously measure temperature of a semiconductor component (e.g., a silicon wafer) for multiple times of manufacturing processes, it is clear that temperature values of temperature measured by the optical thermometer 11 that have not been filtered using the filtering process (hereinafter also referred to as original temperature values 301) vary greatly (i.e., are inconsistent) in a time period from a 6^{th} second to a 7^{th} second in the multiple times of manufacturing processes within the aforesaid range of relatively low temperatures. In comparison, temperature values of temperature measured by the optical thermometer 11 that have been filtered by using the filtering process (hereinafter also referred to as filtered temperature values 302) are relatively more consistent in the aforesaid time period within the aforesaid range of relatively low temperatures. Consequently, the filtered temperature values 302, with the aid of the filtering process, have less errors than the original temperature values 301 when temperature being measured by the optical thermometer 11 is within the range of relatively low temperatures.

In step 204, the reference thermometer 14 measures the temperature of the test semiconductor element to obtain a reference temperature value of the test semiconductor element, and outputs the reference temperature value to the computing device 13.

In step 205, the processor 132 obtains the reference temperature value of the test semiconductor element that is currently measured by the reference thermometer 14 at the pre-process time point.

In step 206, the processor 132 stores the filtered pre-process value and the reference temperature value (which are the temperature-related data previously mentioned) in the storage 131.

In step 207, the processor 132 calculates a temperature difference between the reference temperature value and the preset temperature value corresponding to the pre-process time point.

In step 208, the processor 132 calculates a reference parameter based on the temperature difference thus calculated in step 207. The reference parameter indicates a power of the temperature control device 12. In this embodiment, an algorithm of proportional-integral-derivative (PID) control is utilized to calculate the reference parameter based on the temperature difference. Since the algorithm of PID control has been well known to one skilled in the relevant art, detailed explanation of the same is omitted herein for the sake of brevity.

In step 209, the processor 132 controls the set of heating modules 121 of the temperature control device 12 based on the reference parameter to achieve temperature control.

In step 210, the processor 132 obtains the conversion model by establishing the conversion model based on the filtered pre-process values and the reference temperature values stored in the storage 131, and stores the conversion model thus obtained in the storage 131. Specifically, the processor 132 builds a lookup table as the conversion model. The lookup table records plural offset values that are related respectively to the pre-process time points. Each of the offset values is a difference between the filtered pre-process value that is obtained from the pre-process temperature value which is measured at the corresponding one of the pre-process time points, and the reference temperature value that is measured at the corresponding one of the pre-process time points.

In some embodiments, step 203 for performing the filtering process is omitted. Accordingly, in step 206, the processor 132 stores in the storage 131 the pre-process temperature value instead of the filtered pre-process value; in step 210, the processor 132 establishes the conversion model based on the pre-process temperature values that are stored respectively at the pre-process time points, and the reference temperature values that are stored respectively at the pre-process time points. That is to say, each of the offset values recorded in the lookup table is a difference between one of the pre-process temperature values and one of the reference temperature values.

FIG. 7 exemplarily illustrates the recipe temperature curve (which is formed by the preset temperature values, and is represented by a dashed line), the reference temperature values (which are represented by a thick solid line), the pre-process temperature values (which are represented by a thin solid line), and the filtered pre-process values (which are represented by a dashed-dotted line) in the pre-processing procedure.

It should be noted that in a scenario where the optical thermometer 11 and the reference thermometer 14 simultaneously measure temperature of an arbitrary semiconductor component (e.g., a silicon wafer) that is heated according to an arbitrary temperature curve in an arbitrary manufacturing process, a temperature value of the temperature measured by the optical thermometer 11 is more inaccurate than a temperature value of the temperature measured by the reference thermometer 14, and thus the former is hereinafter also referred to as an inaccurate temperature value and the latter is hereinafter also referred to as an accurate temperature value. By executing the pre-processing procedure specifically for the arbitrary semiconductor component, the arbitrary temperature curve and the arbitrary manufacturing process, the conversion model (i.e., the lookup table), which records corresponding relationships between inaccurate temperature values and accurate temperature values for different time points in the arbitrary manufacturing process, would be established. In this way, for one of the time points of the arbitrary manufacturing process, one of the inaccurate temperature values can be conveniently converted to the corresponding one of the accurate temperature values by using the conversion model. As a result, accuracy of temperature measurement may be improved, and temperature control specifically for the arbitrary semiconductor component, the arbitrary temperature curve and the arbitrary manufacturing process may be achieved.

During the semiconductor manufacturing process, the set of heating modules 121 of the temperature control device 12 heats a target semiconductor element (e.g., a silicon wafer) held by the carrier, and the optical thermometer 11 continuously measures temperature of the target semiconductor element heated by the temperature control device 12. It should be noted that the target semiconductor element is identical to the test semiconductor element. As previously mentioned, on the premise that the pre-processing procedure and the semiconductor manufacturing process are stable, similar or identical semiconductor elements (i.e., the test semiconductor element and the target semiconductor element) each being heated according to the recipe temperature curve should have similar or identical temperatures at the corresponding (i.e., equivalent) time point respectively in the pre-processing procedure and the semiconductor manufacturing process, and results of measurements of the optical thermometer 11 at the corresponding time point respectively in the pre-processing procedure and the semiconductor manufacturing process should be similar or identical.

The semiconductor manufacturing process includes steps 401 to 406 as shown in FIG. 4 and delineated below. It should be noted that steps 401 to 406 are executed at each of the process time points.

In step 401, the optical thermometer 11 measures the temperature of the target semiconductor element to obtain a process temperature value of the temperature of the target semiconductor element, and outputs the process temperature value to the computing device 13.

In step 402, in response to obtaining the process temperature value of the target semiconductor element that is currently measured by the optical thermometer 11 at the process time point, the processor 132 performs the filtering process on the process temperature value of the target semiconductor element obtained at the process time point so as to obtain a filtered process value. As what have been previously mentioned, the filtering process herein is utilized to reduce errors in measurement of temperature by the optical thermometer 11 within the range of relatively low temperatures. At the same time, accuracy of temperature control to be performed based on the measurement may be benefited, accordingly.

In step 403, the processor 132 converts the filtered process value to a converted temperature value by using the conversion model. Specifically, the processor 132 obtains, from the lookup table, one of the offset values that is related to the pre-process time point corresponding to the process time point. For example, when the process time point is the 10^{th} second from the start of the semiconductor manufacturing process, the processor 132 would obtain, from the lookup table, one of the offset values related to the pre-process time point that is the 10^{th} second from the start of the pre-processing procedure. Then, the processor 132 calculates the converted temperature value by subtracting from the filtered process value the offset value thus obtained.

In step 404, the processor 132 calculates a temperature difference between the converted temperature value and the preset temperature value corresponding to the process time point.

In step 405, the processor 132 calculates an adjustment parameter based on the temperature difference thus calculated in step 404. The adjustment parameter indicates the power of the temperature control device 12. In this embodiment, the processor 132 utilizes the algorithm of PID control to calculate the adjustment parameter based on the temperature difference. It should be noted that the converted temperature value obtained in step 403 is ideally equal to one of the reference temperature values that is stored at the pre-process time point in the pre-processing procedure which corresponds to the process time point. Thus, for each of the process time points and the corresponding one of the pre-process time points, the temperature difference calculated in step 404 is ideally equal to the temperature difference calculated in step 207. Therefore, parameters related to the algorithm of PID control used in the pre-processing procedure can be maintained (i.e., no adjustment is needed) for being used again in the semiconductor manufacturing process, thereby enhancing reusability of the parameters related to the algorithm of PID control and enhancing convenience of using the method according to the disclosure.

In step 406, the processor 132 controls the set of heating modules 121 of the temperature control device 12 based on the adjustment parameter to achieve temperature control.

In some embodiments, step 402 for performing the filtering process is omitted. Accordingly, in step 403, the processor 132 calculates the converted temperature value by subtracting the offset value from the process temperature value.

In a variant embodiment of the system, the system includes plural optical thermometers 11 (for example, see FIG. 8 or 9). At each of the process time points in the semiconductor manufacturing process, in response to obtaining the process temperature values of the temperature of the target semiconductor element that are currently measured respectively by the optical thermometers 11 at the process time point, the processor 132 is configured to perform a process of sensor fusion on the process temperature values of the target semiconductor element (which may be actually related to the temperature of the carrier) to obtain a combined temperature value, and to convert the combined temperature value to a converted temperature value by using the conversion model.

FIG. 5 illustrates an example of performing temperature control based on the recipe temperature curve (which is plotted as a dashed line) and the reference temperature values (which are plotted as a thick solid line) measured by the reference thermometer 14, and FIG. 6 illustrates an example of performing temperature control based on the recipe temperature curve (which is plotted as a dashed line) and the converted temperature values (which are plotted as a thick solid line). In each of FIGS. 5 and 6, a level of temperature control (which is plotted as a thin solid line and represented by a percentage of intensity) is also illustrated for reference. It should be noted that the converted temperature values are derived by using the conversion model from the process temperature values that are measured by the optical thermometer 11 and that are more inaccurate than the reference temperature values (in some embodiments, the process temperature values may be further filtered by using the filtering process). However, it is evident that the converted temperature values in FIG. 6 are very similar to the reference temperature values in FIG. 5, and hence results of temperature control (i.e., actual temperature values of objects being heated, e.g., a silicon wafer, which are plotted as dashed-dotted lines) achieved in FIGS. 5 and 6 are extremely similar. That is to say, the method of temperature control according to the disclosure may mitigate impact of errors occurring in temperature measurement, and therefore may achieve accurate temperature control according to the recipe temperature curve.

To sum up, for the method, the system and the computing device 13 of temperature control in a semiconductor manufacturing process according to the disclosure, the conversion model is established in advance (i.e., prior to performing temperature control in the semiconductor manufacturing process). The conversion model is a lookup table that records, for different time points, offset values each being a difference between a temperature value measured by the optical thermometer 11 (which, due to light interference in measurement, is relatively inaccurate at reflecting actual temperature of a semiconductor element being heated) and a temperature value measured by the reference thermometer 14 (which is relatively accurate at reflecting actual temperature of a semiconductor element being heated because measurement is not interfered by light, hereinafter also referred to as an actual temperature value). Consequently, a process temperature value measured by the optical thermometer 11 in the semiconductor manufacturing process can be converted to the actual temperature value through simple arithmetic based on the conversion model, and then the actual temperature value could be further used to accurately control the temperature control device 12. In this way, issues of interference in temperature measurement caused by stray light or light emitted from the set of heating modules 121 (e.g., halogen lamps) in the semiconductor manufacturing process may be effectively alleviated. Since only simple arithmetic is involved, no high-performance hardware (e.g., high-sampling-rate optical thermometers or high-speed computers) is required, thereby reducing hardware costs. It is worthy of note that before using the conversion model to convert process temperature values measured by the optical thermometer 11 in the semiconductor manufacturing process, the filtering process may be performed on the process temperature values so as to reduce errors in measurement of the optical thermometer 11 when temperature is within the range of relatively low temperatures (e.g., from 280 to 285 degrees Celsius).

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of temperature control in a semiconductor manufacturing process that involves an optical thermometer and a temperature control device, the optical thermometer continuously measuring temperature of a target semiconductor element heated by the temperature control device during the semiconductor manufacturing process that has plural successive process time points which correspond respectively to plural preset temperature values, the method comprising, at each of the process time points:
in response to obtaining a process temperature value of the temperature of the target semiconductor element that is currently measured by the optical thermometer at the process time point, converting the process temperature value of the target semiconductor element to a converted temperature value by using a conversion model;
calculating a temperature difference between the converted temperature value and the preset temperature value corresponding to the process time point;
calculating an adjustment parameter based on the temperature difference thus calculated, the adjustment parameter indicating a power of the temperature control device; and
controlling the temperature control device based on the adjustment parameter to achieve temperature control.

2. The method as claimed in claim 1, further comprising a pre-processing procedure that involves a reference thermometer and the optical thermometer continuously measuring temperature of a test semiconductor element heated by the temperature control device and that has plural successive pre-process time points corresponding respectively to the process time points, the test semiconductor element being identical to the target semiconductor element, the pre-processing procedure including, at each of the pre-process time points:
obtaining a pre-process temperature value of the temperature of the test semiconductor element that is currently measured by the optical thermometer at the pre-process time point;
obtaining a reference temperature value of the temperature of the test semiconductor element that is currently measured by the reference thermometer at the pre-process time point;
storing the pre-process temperature value and the reference temperature value that are measured at the pre-process time point;
calculating a temperature difference between the reference temperature value and the preset temperature value corresponding to the pre-process time point;
calculating a reference parameter based on the temperature difference thus calculated, the reference parameter indicating the power of the temperature control device; and
controlling the temperature control device based on the reference parameter to achieve temperature control.

3. The method as claimed in claim 2, wherein the pre-processing procedure further includes:
obtaining the conversion model based on the pre-process temperature values that are stored respectively at the pre-process time points, and the reference temperature values that are stored respectively at the pre-process time points.

4. The method as claimed in claim 3, the method further comprising:
at each of the pre-process time points, performing a filtering process on the test temperature value of the test semiconductor element obtained at the pre-process time point so as to obtain a filtered pre-process value,
wherein storing the pre-process temperature value and the reference temperature value is to store the filtered pre-process value and the reference temperature, and
wherein obtaining the conversion model is to establish the conversion model based on the reference temperature values and the filtered pre-process values that are obtained respectively from the pre-process temperature values.

5. The method as claimed in claim 4, wherein converting the process temperature value includes:
performing the filtering process on the process temperature value of the target semiconductor element obtained at the process time point so as to obtain a filtered process value; and
converting the filtered process value to the converted temperature value by using the conversion model.

6. The method as claimed in claim 5, wherein:
obtaining the conversion model is to build a lookup table as the conversion model, the lookup table recording plural offset values that are related respectively to the pre-process time points, each of the offset values being a difference between the filtered pre-process value that is obtained from the pre-process temperature value which is measured at the corresponding one of the pre-process time points, and the reference temperature value that is measured at the corresponding one of the pre-process time points; and
at each of the process time points, converting the process temperature value of the target semiconductor element includes
from the lookup table, obtaining one of the offset values that is related to the pre-process time point corresponding to the process time point, and
calculating the converted temperature value by subtracting from the filtered process value the offset value thus obtained.

7. A computing device, adapted to perform temperature control in a semiconductor manufacturing process that involves an optical thermometer and a temperature control device, said computing device electrically connected to the optical thermometer and the temperature control device, the optical thermometer continuously measuring temperature of a target semiconductor element heated by the temperature control device during the semiconductor manufacturing process that has plural successive process time points which correspond respectively to plural preset temperature values, said computing device comprising:
a storage configured to store a conversion model; and
a processor electrically connected to said storage, and configured to, at each of the process time points,
in response to obtaining a process temperature value of the temperature of the target semiconductor element that is currently measured by the optical thermometer at the process time point, convert the process temperature value of the target semiconductor element to a converted temperature value by using the conversion model stored in said storage,
calculate a temperature difference between the converted temperature value and the preset temperature value corresponding to the process time point,
calculate an adjustment parameter based on the temperature difference thus calculated, the adjustment parameter indicating a power of the temperature control device, and
control the temperature control device based on the adjustment parameter to achieve temperature control.

8. The computing device as claimed in claim 7, further adapted to perform temperature control in a pre-processing procedure that involves a reference thermometer and the optical thermometer continuously measuring temperature of a test semiconductor element heated by the temperature control device and that has plural successive pre-process time points corresponding respectively to the process time points, the test semiconductor element being identical to the target semiconductor element, wherein:
said computing device is further electrically connected to the reference thermometer; and
said processor is further configured to, at each of the pre-process time points,
obtain a pre-process temperature value of the temperature of the test semiconductor element that is currently measured by the optical thermometer at the pre-process time point,
obtain a reference temperature value of the test semiconductor element that is currently measured by the reference thermometer at the pre-process time point,
store in said storage the pre-process temperature value and the reference temperature value that are measured at the pre-process time point,
calculate a temperature difference between the reference temperature value and the preset temperature value corresponding to the pre-process time point,
calculate a reference parameter based on the temperature difference thus calculated, the reference parameter indicating the power of the temperature control device, and
control the temperature control device based on the reference parameter to achieve temperature control.

9. The computing device as claimed in claim 8, wherein said processor is further configured to, in the pre-processing procedure:
obtain the conversion model based on the pre-process temperature values that are stored respectively at the pre-process time points, and the reference temperature values that are stored respectively at the pre-process time points.

10. The computing device as claimed in claim 9, wherein:
said processor is further configured to, at each of the pre-process time points, perform a filtering process on the test temperature value of the test semiconductor element obtained at the pre-process time point so as to obtain a filtered pre-process value, and store the filtered pre-process value in said storage; and
said processor is configured to obtain the conversion model by establishing the conversion model based on the reference temperature values and the filtered pre-process values that are obtained respectively from the pre-process temperature values.

11. The computing device as claimed in claim 10, wherein said processor is configured to convert the process temperature value by:
performing the filtering process on the process temperature value of the target semiconductor element obtained at the process time point so as to obtain a filtered process value; and
converting the filtered process value to the converted temperature value by using the conversion model.

12. The computing device as claimed in claim 11, wherein:
said processor is configured to obtain the conversion model by building a lookup table as the conversion model, the lookup table recording plural offset values that are related respectively to the pre-process time points, each of the offset values being a difference between the filtered pre-process value that is obtained from the pre-process temperature value which is measured at the corresponding one of the pre-process time points, and the reference temperature value that is measured at the corresponding one of the pre-process time points; and
at each of the process time points, said processor is configured to convert the process temperature value of the target semiconductor element by,
from the lookup table, obtaining one of the offset values that is related to the pre-process time point corresponding to the process time point, and
calculating the converted temperature value by subtracting from the filtered process value the offset value thus obtained.

13. A system of temperature control in a semiconductor manufacturing process, said system comprising:
a temperature control device including
a carrier that is configured to hold a target semiconductor element, and
a set of heating modules that is configured to heat the target semiconductor element;
an optical thermometer configured to continuously measure temperature of said carrier as temperature of the target semiconductor element; and
a computing device according to claim 7.

14. The system as claimed in claim 13, wherein said carrier is a ring.

15. The system as claimed in claim 13, wherein said carrier is a susceptor.

16. The system as claimed in claim 13, wherein:
said optical thermometer includes plural optical thermometers; and
at each of the process time points, in response to obtaining the process temperature values of the temperature of the target semiconductor element that are currently measured respectively by the optical thermometers at the process time point, said processor is configured to perform a process of sensor fusion on the process temperature values of the target semiconductor element to obtain a combined temperature value, and to convert the combined temperature value to a converted temperature value by using the conversion model.

17. The system as claimed in claim 13, further comprising a reference thermometer electrically connected to said computing device, wherein:
said carrier is further configured to hold a test semiconductor element that is identical to the target semiconductor element;
said set of heating modules is further configured to heat the test semiconductor element;
said reference thermometer and said optical thermometer are configured to continuously measure temperature of said carrier as temperature of the test semiconductor element;
said computing device is further adapted to perform temperature control in a pre-processing procedure that involves a reference thermometer and the optical thermometer continuously measuring temperature of a test semiconductor element heated by the temperature control device and that has plural successive pre-process time points corresponding respectively to the process time points, the test semiconductor element being identical to the target semiconductor element;
said computing device is further electrically connected to the reference thermometer; and
said processor of said computing device is further configured to, at each of the pre-process time points,
obtain a pre-process temperature value of the temperature of the test semiconductor element that is currently measured by the optical thermometer at the pre-process time point,
obtain a reference temperature value of the test semiconductor element that is currently measured by the reference thermometer at the pre-process time point,
store in said storage the pre-process temperature value and the reference temperature value that are measured at the pre-process time point,
calculate a temperature difference between the reference temperature value and the preset temperature value corresponding to the pre-process time point,
calculate a reference parameter based on the temperature difference thus calculated, the reference parameter indicating the power of the temperature control device, and
control the temperature control device based on the reference parameter to achieve temperature control.

18. The system as claimed in claim 17, wherein said processor of said computing device is further configured to, in the pre-processing procedure, obtain the conversion model based on the pre-process temperature values that are stored respectively at the pre-process time points, and the reference temperature values that are stored respectively at the pre-process time points.

19. The system as claimed in claim 18, wherein:
said processor of said computing device is further configured to, at each of the pre-process time points, perform a filtering process on the test temperature value of the test semiconductor element obtained at the pre-process time point so as to obtain a filtered pre-process value, and store the filtered pre-process value in said storage; and
said processor of said computing device is configured to obtain the conversion model by establishing the conversion model based on the reference temperature values and the filtered pre-process values that are obtained respectively from the pre-process temperature values.

20. The system as claimed in claim 19, wherein said processor is configured to convert the process temperature value by:
performing the filtering process on the process temperature value of the target semiconductor element obtained at the process time point so as to obtain a filtered process value; and
converting the filtered process value to the converted temperature value by using the conversion model.

21. The system as claimed in claim 20, wherein:
said processor is configured to obtain the conversion model by building a lookup table as the conversion model, the lookup table recording plural offset values that are related respectively to the pre-process time points, each of the offset values being a difference between the filtered pre-process value that is obtained from the pre-process temperature value which is measured at the corresponding one of the pre-process time points, and the reference temperature value that is measured at the corresponding one of the pre-process time points; and
at each of the process time points, said processor is configured to convert the process temperature value of the target semiconductor element by,
from the lookup table, obtaining one of the offset values that is related to the pre-process time point corresponding to the process time point, and
calculating the converted temperature value by subtracting from the filtered process value the offset value thus obtained.
